(19) United States
(12) Patent Application Publication
(10) Pub. No.: US 2019/0051666 A1
(43) Pub. Date: Feb. 14, 2019

(54) SEMICONDUCTOR DEVICE AND FABRICATION METHOD THEREOF

(71) Applicant: UNITED MICROELECTRONICS CORP., Hsin-Chu City (TW)

(72) Inventors: Wen-Shen Li, Singapore (SG); XIAOYUAN ZHI, Singapore (SG); XINGXING CHEN, Singapore (SG); Ching-Yang Wen, Pingtung County (TW)

(21) Appl. No.: 15/691,757

(22) Filed: Aug. 31, 2017

(30) Foreign Application Priority Data
Aug. 14, 2017 (CN) 201710690789.1

(51) Int. Cl. H01L 27/12; H01L 23/48; H01L 21/84; H01L 21/768; H01L 21/683

(52) U.S. Cl. CPC H01L 27/1203; H01L 23/481; H01L 21/84; H01L 21/76802; H01L 21/76877; H01L 24/05; H01L 21/76846; H01L 21/76898; H01L 2221/68327; H01L 2221/68359; H01L 21/6835

(57) ABSTRACT

A semiconductor device includes a substrate having a frontside and a backside. The substrate includes a semiconductor layer and a buried insulator layer. A transistor is disposed on the semiconductor layer. An interlayer dielectric (ILD) layer is disposed on the frontside and covering the transistor. A contact structure penetrates through the ILD layer, the semiconductor layer and the buried insulator layer. A silicide layer caps an end surface of the contact structure on the backside. A passive element is disposed on the backside of the substrate. The contact structure is electrically connected to the passive element.

### CROSS REFERENCE TO RELATED APPLICATION

This application claims the priority from CN application No. 201710690789.1, filed Aug. 14, 2017, which is included in its entirety herein by reference.

### BACKGROUND OF THE INVENTION

### 1. Field of the Invention

The present invention relates to the field of semiconductor technology, and in particular to a silicon-on-insulator (SOI) semiconductor device and a fabrication method thereof.

### 2. Description of the Prior Art

Devices fabricated using semiconductor-on-insulator (SOI) technologies may exhibit certain performance improvements in comparison with comparable devices built directly in a bulk silicon substrate. Generally, an SOI wafer includes a thin device layer of semiconductor material, a handle substrate, and a thin buried insulator layer, such as a buried oxide or BOX layer, physically separating and electrically isolating the device layer from the handle substrate. Integrated circuits are fabricated using the semiconductor material of the device layer.

In semiconductor devices fabricated using SOI technology, it is sometimes necessary to process the backside of the wafer (backside processes) to further produce other circuit elements such as passive components comprising inductors or capacitors. Therefore, there is a need to form a conductive contact structure (body contact) in the wafer that can be electrically coupled to the backside of the wafer. Typically, to protect the conductive contact structure against the etchant such as tetramethylammonium hydroxide (TMAH) during the fabrication of the conductive contact structure an insulating liner is required to cover the conductive contact structure. The disadvantage of this practice is that the conductive contact structure with the insulating liner leads to apparent induced charge effect.

### SUMMARY OF THE INVENTION

It is one object of the present invention to provide a semiconductor device and a method of making the same, which can improve the deficiencies and disadvantages of the prior art.

According to one aspect of the invention, a semiconductor device is disclosed. The semiconductor device includes a substrate having a frontside and a backside. The substrate includes a semiconductor layer and a buried insulator layer. A transistor is disposed on the semiconductor layer. An interlayer dielectric (ILD) layer is disposed on the frontside and covering the transistor. A contact structure penetrates through the ILD layer, the semiconductor layer and the buried insulator layer. A silicide layer caps an end surface of the contact structure on the backside. A passive element is disposed on the backside of the substrate. The contact structure is electrically connected to the passive element.

According to one embodiment of the present invention, the contact structure comprises a conductive liner and a metal layer. The metal layer is surrounded by the conductive liner.

According to one embodiment of the present invention, the conductive liner is in direct contact with the semiconductor layer.

According to one embodiment of the present invention, the metal silicide layer comprises nickel silicide, cobalt silicide, or titanium silicide.

According to one embodiment of the present invention, the passive element comprises an inductor, a capacitor, or a resistor.

According to one embodiment of the present invention, the metal silicide layer is in direct contact with a contact pad of the passive element.

According to one embodiment of the present invention, a first dielectric layer and a second dielectric layer are disposed on the backside. The contact pad is disposed in the first dielectric layer and the passive element is disposed in the second dielectric layer.

According to another aspect of the invention, a method for fabricating a semiconductor device is disclosed. A semiconductor-on-insulator (SOI) wafer having a frontside and a backside is provided. The SOI wafer comprises a semiconductor layer, a buried insulator layer, and a substrate layer. At least one transistor is formed on the semiconductor layer. An interlayer dielectric (ILD) layer is formed on the frontside and the ILD layer covers the at least one transistor. A contact hole is formed. The contact hole penetrates through the ILD layer, the semiconductor layer and the buried insulator layer so as to expose a portion of the substrate layer. A silicide layer is formed at a bottom surface of the contact hole on the exposed portion of the substrate layer. The contact hole is filled with a conductor, thereby forming a contact structure. A passive element is formed on the backside of the substrate. The contact structure is electrically connected to the passive element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 14 are schematic cross-sectional views showing an exemplary method of manufacturing a semiconductor device according to one embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present disclosure.

The following detailed description is, therefore, not to be taken in a limiting sense, and the scope of the present invention is defined only by the appended claims, along with the full scope of equivalents to which such claims are entitled. One or more implementations of the present invention will now be described with reference to the attached drawings, wherein like reference numerals are used to refer to like elements throughout, and wherein the illustrated structures are not necessarily drawn to scale.

The present invention discloses a silicon-on-insulator (SOI) semiconductor device and a method for manufacturing the same. The SOI semiconductor device, for example, may be applicable in the technical field of radio frequency (RF) components, but is not limited thereto.

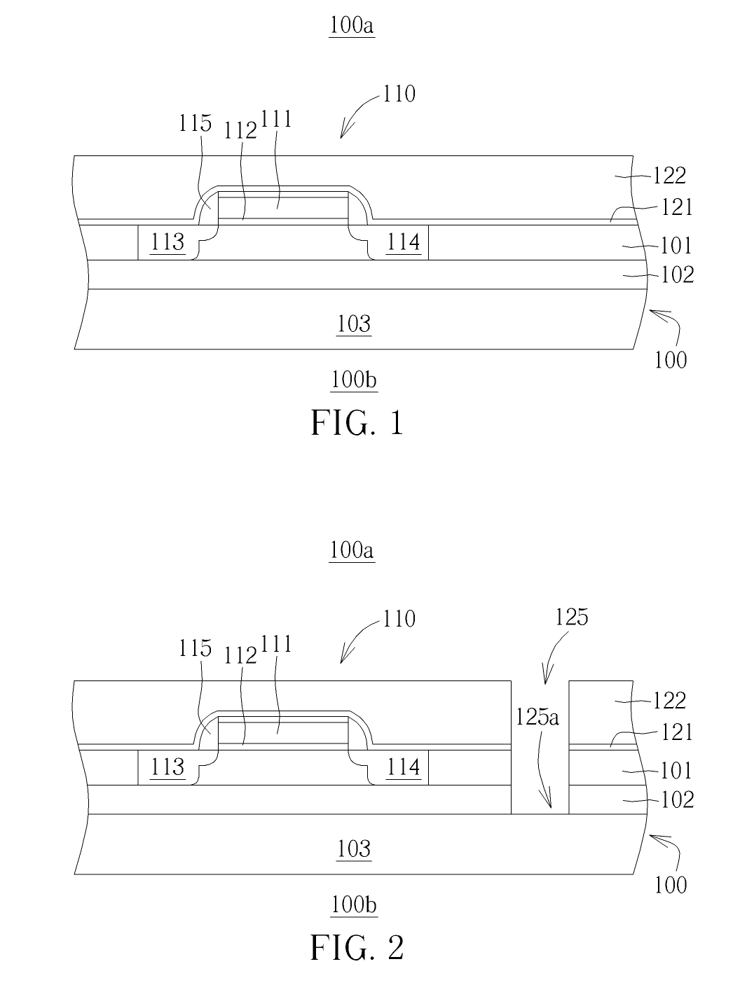

Referring to FIGS. 1 to 14, which are schematic cross-sectional views showing an exemplary method of manufacturing a semiconductor device according to one embodiment of the present invention. As shown in FIG. 1, there is provided a silicon-on-insulator (SOI) wafer (or substrate) 100 having a frontside 100a and a backside 100b. The SOI wafer 100 comprises a semiconductor layer 101, a buried insulator layer 102 and a substrate (handle substrate) layer 103. The buried insulator layer 102 physically separates and electrically isolates the semiconductor layer 101 from the substrate layer 103.

According to one embodiment of the present invention, the semiconductor layer 101 may include silicon, such as monocrystalline silicon, the buried insulating layer 102 may include silicon dioxide, and the substrate layer 103 may include silicon, but not limited thereto.

Next, at least one transistor 110 is formed on the semiconductor layer 101. It is to be understood that a plurality of transistors or other electronic components may be formed on the semiconductor layer 101. For the sake of simplicity, only one transistor 110 is illustrated in the drawings. According to one embodiment of the present invention, the transistor 110 may comprise a gate 111, a gate dielectric layer 112 provided between the gate 111 and the semiconductor layer 101, a source doping region 113, and a drain doping region 114. A spacer 115 may be formed on each sidewall of the gate 111.

Next, an etch stop layer 121 and an interlayer dielectric (ILD) layer 122 are sequentially formed on the semiconductor layer 101 and the transistor 110 on the frontside 100a. According to one embodiment of the present invention, the etch stop layer 121 may be a silicon nitride layer, but is not limited thereto. According to one embodiment of the present invention, the ILD layer 122 may be a silicon dioxide layer, but is not limited thereto.

As shown in FIG. 2, a contact hole 125 extending through the ILD layer 122, the etch stop layer 121, the semiconductor layer 101, and the buried insulator layer 102 is formed. The bottom portion 125a of the contact hole 125 exposes a portion of the substrate layer 103.

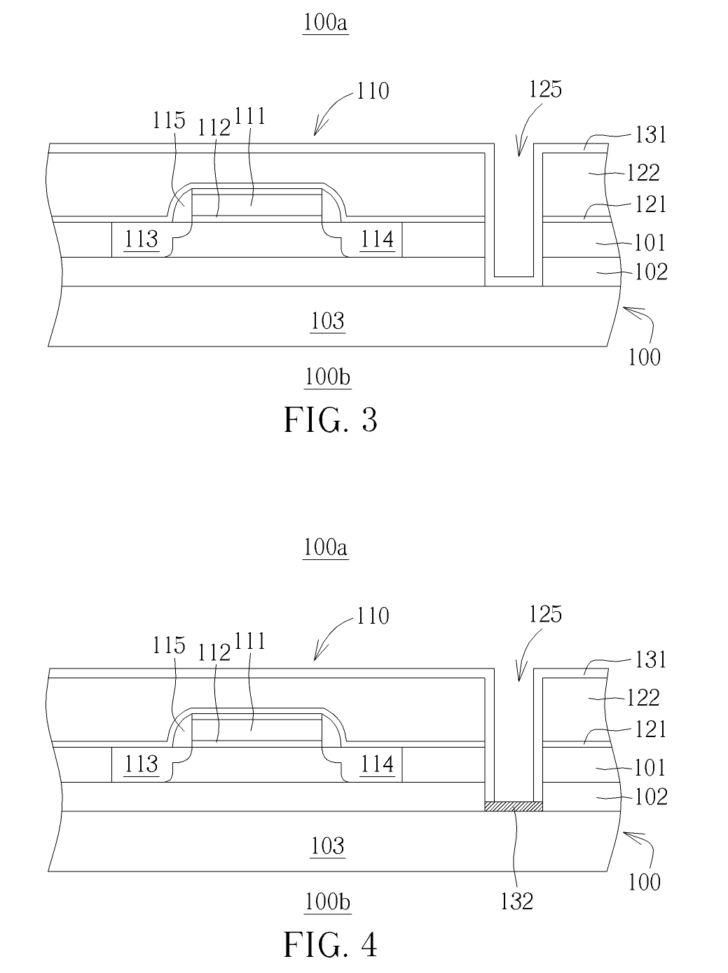

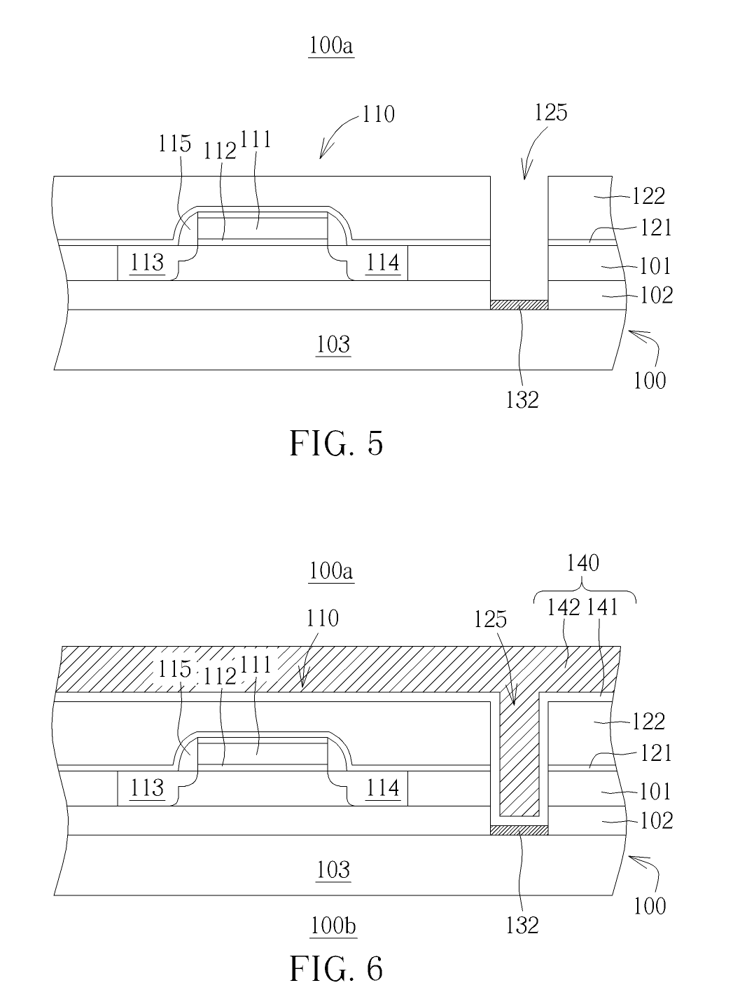

As shown in FIG. 3 to FIG. 5, subsequently, a silicidation process is performed. A metal layer 131 (FIG. 3), for example, nickel, cobalt or titanium, is formed on the ILD layer 122 and the inner surface of the contact hole 125 on the frontside 100a. Next, a rapid thermal annealing (RTP) process is performed to form a metal silicide (or silicide) layer 132 on the substrate layer 103 of the portion exposed at the bottom 125a of the contact hole 125 (FIG. 4). According to one embodiment of the present invention, the metal silicide layer 132 may comprise, but is not limited to, nickel silicide, cobalt silicide, or titanium silicide. Next, the unreacted metal layer 131 is removed and the metal silicide layer 132 is left at the bottom 125a of the contact hole 125 (FIG. 5).

As shown in FIG. 6, the contact hole 125 is then filled with a conductive material 140, for example, the conductive material 140 may include a conductive liner 141 and a metal layer 142. The metal layer 142 is surrounded by the conductive liner 141 within the contact hole 125. According to one embodiment of the present invention, for example, the metal layer 142 is a tungsten layer. The conductive liner 141 is in direct contact with the semiconductor layer 101.

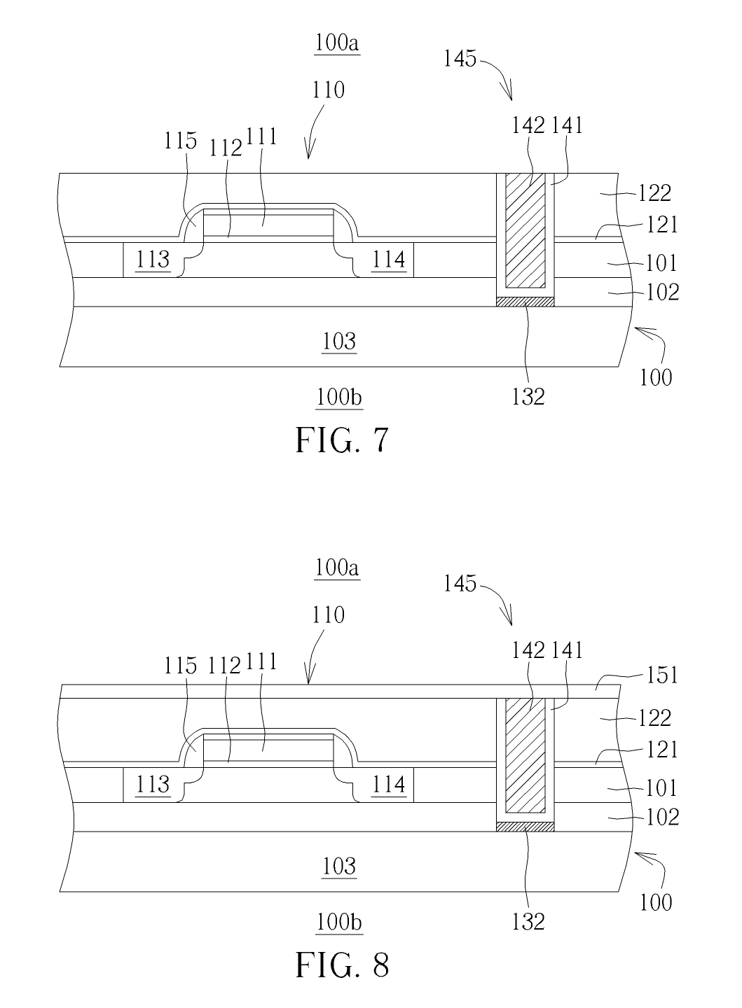

As shown in FIG. 7, a tungsten chemical mechanical polishing (WCMP) process is carried out to remove the excess conductive material 140 on the ILD layer 122 so that a contact structure 145 is formed in the contact hole 125.

As shown in FIG. 8, after completion of the aforementioned WCMP process, a barrier oxide layer 151 is formed on the ILD layer 122 and on the top surface of the contact structure 145.

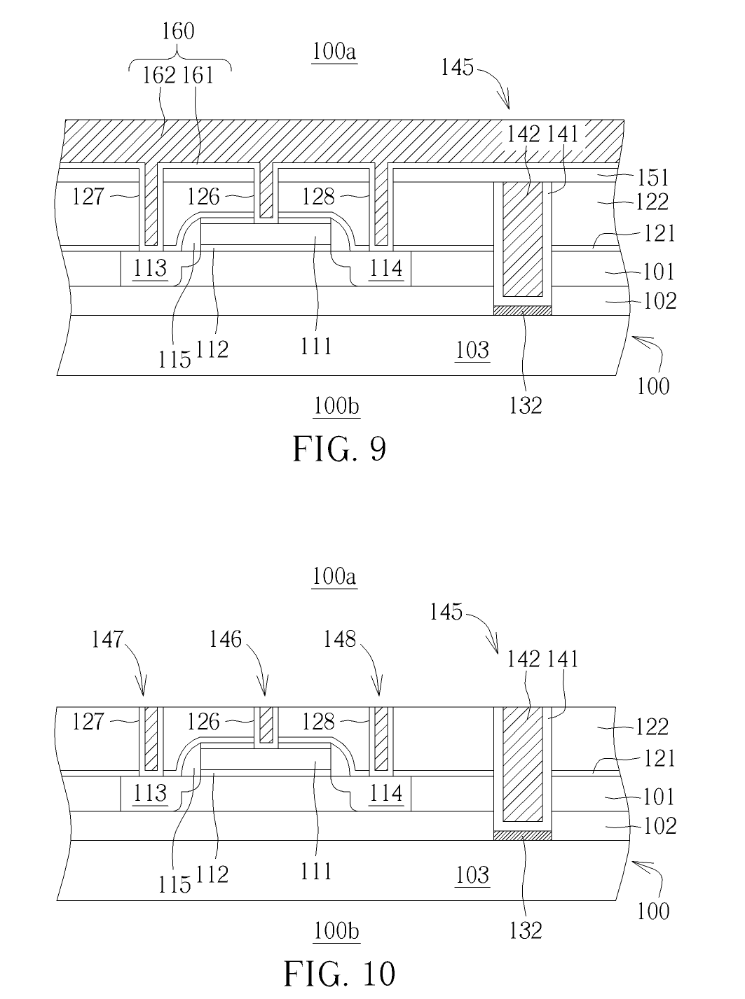

As shown in FIG. 9, contact holes 126, 127 and 128 over the transistor 110 are then etched into the barrier oxide layer 151, the ILD layer 122, and the etch stop layer 121. The contact hole 126 communicates with the gate 111, the contact hole 127 communicates with the source doping region 113, and the contact hole 128 communicates with the drain doping region 114. The contact holes 126, 127 and 128 are then filled with a conductive material 160. For example, the conductive material 160 may include a conductive liner 161 and a metal layer 162. According to one embodiment of the present invention, for example, the metal layer 162 is a tungsten layer.

As shown in FIG. 10, a tungsten chemical mechanical polishing (WCMP) process is then carried out to remove the excess conductive material 160 and the barrier oxide layer 151 on the ILD layer 122 so as to form contact structure 146, 147, and 148, which are electrically connected to the gate 111, the source doping region 113, and the drain doped region 114, respectively.

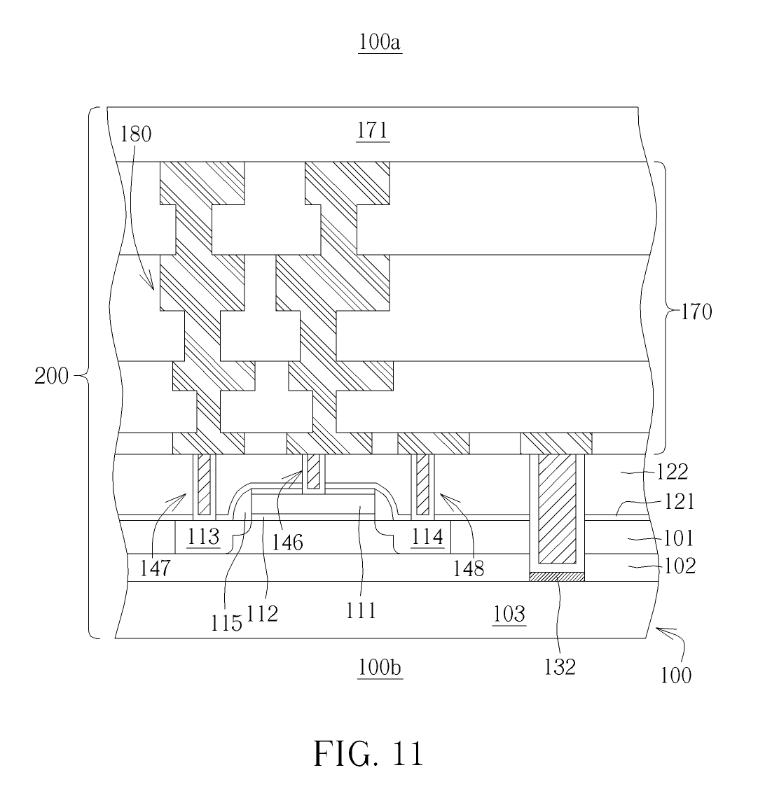

As shown in FIG. 11, an inter-metal dielectric (IMD) layer 170 and a metal interconnect structure 180 are formed on the ILD layer 122 and the contact structures 145, 146, 147, and 148. The IMD layer 170 may comprise a plurality of layers of dielectric material or insulating layers, and the metal interconnect structure 180 may be formed in the multiple layers of dielectric material or the insulating layers, respectively. The metallization process on the frontside 100a is a well-known technique, so the details of the process are omitted. Next, a passivation layer (or protective layer) 171 may be formed on the IMD layer 170. At this point, the process steps performed on the frontside 100a are completed, and a device wafer 200 is formed.

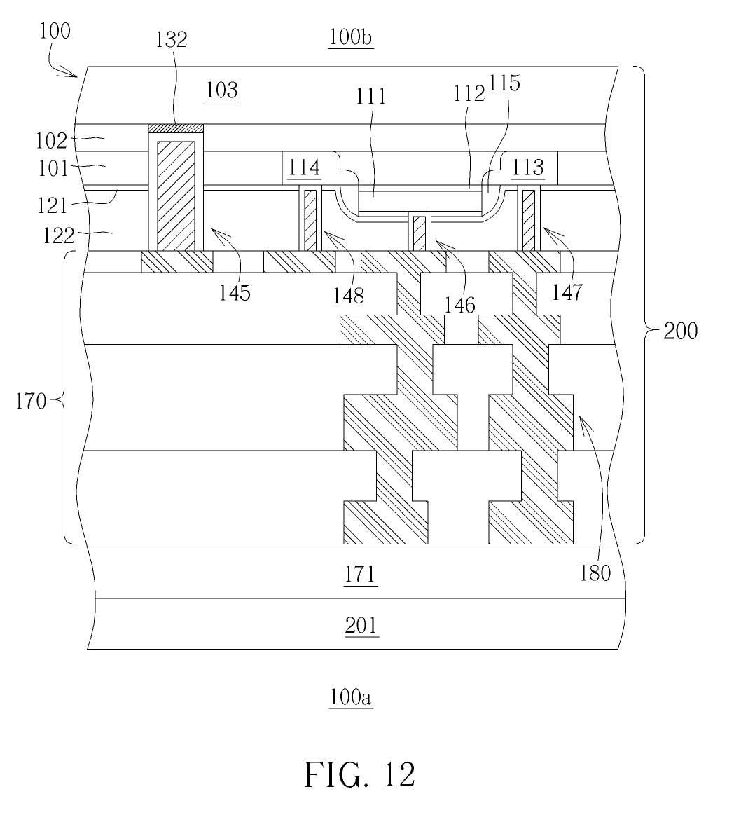

As shown in FIG. 12, a temporary substrate 201 is then bonded to the passivation layer 171 on the ILD layer 122. To facilitate the description of the subsequent process steps on the backside, the device wafers 200 in FIG. 12 is reversed (upside down) compared to that as depicted in FIG. 11. In FIG. 12, the temporary substrate 201 is at the bottom, and the substrate layer 103 is at the top.

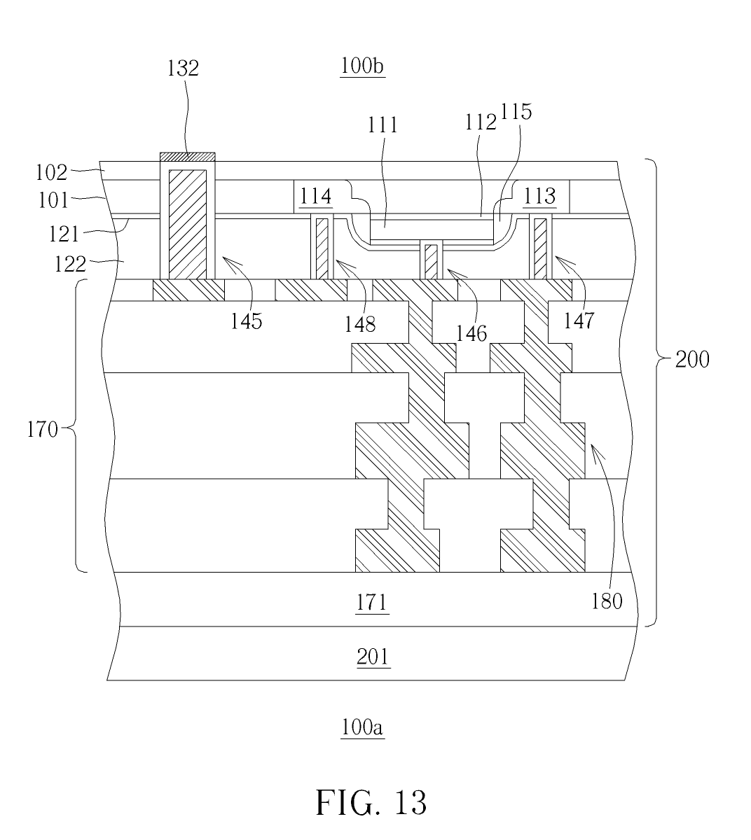

As shown in FIG. 13, after the bonding step of the temporary substrate 201 is completed, the substrate layer 103 is then thinned until the metal silicide layer 132 is exposed. According to one embodiment of the present invention, the method of thinning the substrate layer 103 may be performed by polishing, grinding or etching, but is not limited thereto. According to one embodiment of the present invention, the substrate layer 103 may be completely removed, so as to expose the buried insulator layer 102, but not limited thereto.

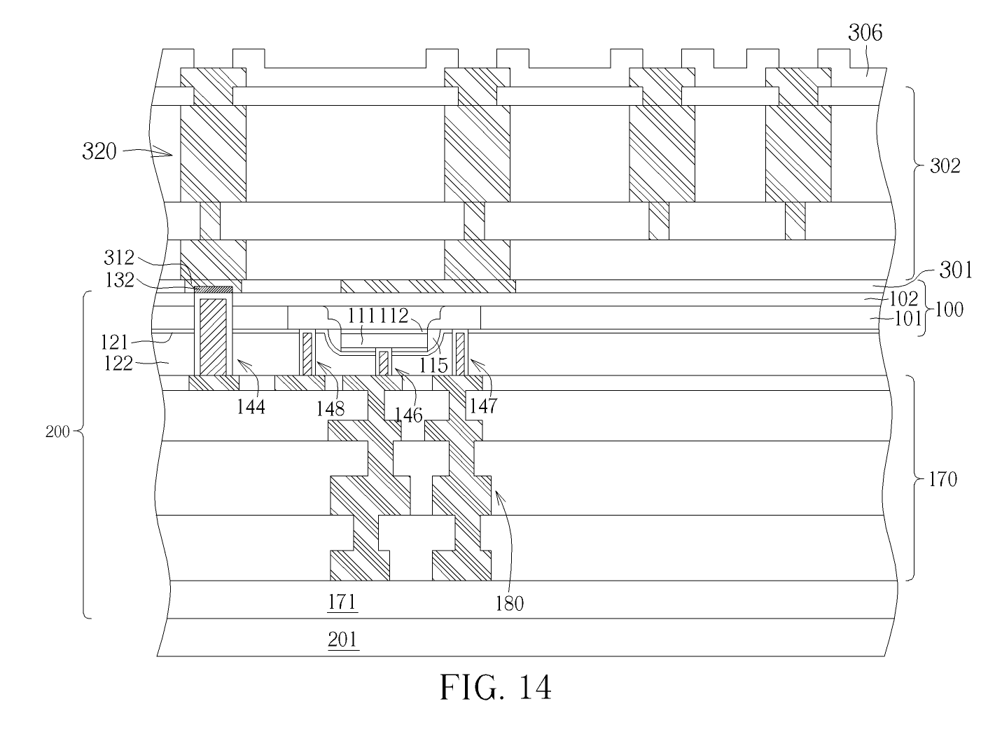

As shown in FIG. 14, a first dielectric layer 301 is formed on the buried insulator layer 102 on the backside 100b. A contact pad 312 is formed on the first dielectric layer 301, where the contact pad 312 is in direct contact with the metal silicide layer 132. According to one embodiment of the present invention, the contact pad 312 may comprise copper, but is not limited thereto. The contact pad 312 may be formed using a copper damascene process.

Next, a second dielectric layer 302 is formed on the first dielectric layer 301. In addition, a passive element 320 is formed in the second dielectric layer 302 on the backside 100b, wherein the passive element 320 may include an inductor, a capacitor, or a resistor. The second dielectric layer 302 may comprise a plurality of layers of dielectric material or insulating layers, and the passive element 320 may be integrally formed in the multiple layers dielectric material or insulating layers. The passive element forming process on the backside 100b is a well-known technique, so the details of process are omitted.

According to one embodiment of the present invention, the contact structure 144 is electrically connected to the passive element 320. The passive element 320 is electrically connected to the contact structure 144 via the contact pad 312 and the metal silicide layer 132. A passivation layer (or protective layer) 306 may be formed on the second dielectric layer 302. Finally, the temporary substrate 201 may be removed and the method of fabricating the semiconductor device according to one embodiment is completed.

As can be seen from FIG. 14, the semiconductor device of the present invention comprises a substrate 100 having a frontside 100a and a backside 100b. The substrate 100 comprises a semiconductor layer 101 and a buried insulator layer 102. At least a transistor 110 is disposed on the semiconductor layer 101. An interlayer dielectric (ILD) layer 122 is provided on the frontside 100a, covering the transistor 110. A contact structure 145 extending through the ILD layer 122, the semiconductor layer 101, and the buried insulator layer 102 is provided. A metal silicide layer 132 covers one end face of the contact structure 145 on the backside 100b. A passive element 320 is disposed on the backside 100b of the substrate 100. The contact structure 145 is electrically connected to the passive element 320.

According to one embodiment of the present invention, the contact structure 145 comprises a conductive liner 141 and a metal layer 142. The metal layer 142 is surrounded by the conductive liner 141.

According to one embodiment of the present invention, the conductive liner 141 is in direct contact with the semiconductor layer 101.

According to one embodiment of the present invention, the metal silicide layer 132 comprises nickel silicide, cobalt silicide, or titanium silicide.

According to one embodiment of the present invention, the passive element 320 comprises an inductor, a capacitor, or a resistor.

According to one embodiment of the present invention, the metal silicide layer 132 is in direct contact with a contact pad 312 of the passive element 320.

According to one embodiment of the present invention, a first dielectric layer 301 and a second dielectric layer 302 are disposed on the backside 100b. The contact pad 312 is disposed in the first dielectric layer 301 and the passive element 320 is disposed in the second dielectric layer 302.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
a substrate having a frontside and a backside, wherein the substrate comprises a semiconductor layer and a buried insulator layer;
at least one transistor disposed on the semiconductor layer;
an interlayer dielectric (ILD) layer disposed on the frontside and covering the at least one transistor;
a contact structure penetrating through the ILD layer, the semiconductor layer and the buried insulator layer;
a silicide layer capping an end surface of the contact structure on the backside, wherein the end surface of the contact structure on the backside is flush with an exposed surface of the buried insulator layer; and
a passive element disposed on the backside of the substrate; wherein the contact structure is electrically connected to the passive element.

2. The semiconductor device according to claim 1, wherein the contact structure comprises a conductive liner and a metal layer surrounded by the conductive liner.

3. The semiconductor device according to claim 2, wherein the conductive liner is in direct contact with the semiconductor layer.

4. The semiconductor device according to claim 1, wherein the silicide layer comprises nickel silicide, cobalt silicide, or titanium silicide.

5. The semiconductor device according to claim 1, wherein the passive element comprises an inductor, a capacitor, or a resistor.

6. The semiconductor device according to claim 1, wherein the silicide layer is in direct contact with a contact pad of the passive element.

7. The semiconductor device according to claim 1 further comprising a first dielectric layer and a second dielectric layer on the backside, wherein the contact pad is disposed in the first dielectric layer and the passive element is disposed in the second dielectric layer.

8. A method for fabricating a semiconductor device, comprising:
providing semiconductor-on-insulator (SOI) wafer having a frontside and a backside, wherein the SOI wafer comprises a semiconductor layer, a buried insulator layer, and a substrate layer;
forming at least one transistor on the semiconductor layer;
forming an interlayer dielectric (ILD) layer on the frontside and covering the at least one transistor;
forming a contact hole penetrating through the ILD layer, the semiconductor layer and the buried insulator layer so as to expose a portion of the substrate layer;
forming a silicide layer at a bottom surface of the contact hole on the exposed portion of the substrate layer;
filling the contact hole with a conductor, thereby forming a contact structure, wherein an end surface of the contact structure is capped by the silicide layer on the backside and the end surface of the contact structure is flush with an exposed surface of the buried insulator layer; and
forming a passive element on the backside of the substrate, wherein the contact structure is electrically connected to the passive element.

9. The method for fabricating a semiconductor device according to claim 8 further comprising:
bonding a temporary substrate onto the ILD layer; and
thinning the substrate layer until the silicide layer is exposed.

10. The method for fabricating a semiconductor device according to claim 9 further comprising:
forming a first dielectric layer on the backside;
forming a contact pad in the first dielectric layer, wherein the contact pad is in direct contact with the silicide layer;
forming a second dielectric layer on the first dielectric layer; and
forming a passive element on the second dielectric layer, wherein the passive element is electrically connected to the contact structure through the contact pad and the silicide layer.

11. The method for fabricating a semiconductor device according to claim 10, wherein the passive element comprises an inductor, a capacitor, or a resistor.

12. The method for fabricating a semiconductor device according to claim 8, wherein the contact structure comprises a conductive liner and a metal layer surrounded by the conductive liner.

13. The method for fabricating a semiconductor device according to claim 12, wherein the conductive liner is in direct contact with the semiconductor layer.

14. The method for fabricating a semiconductor device according to claim 8, wherein the silicide layer comprises nickel silicide, cobalt silicide, or titanium silicide.
